(19) United States
(12) Patent Application Publication
(10) Pub. No.: US 2008/0002374 A1
(43) Pub. Date: Jan. 3, 2008

(54) Substrate with stiffener and manufacturing method thereof

(75) Inventors: Kenji Fukuzono, Kawasaki (JP); Toshihisa Sato, Kawasaki (JP); Yuki Samejima, Kanagawa (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/637,911

(22) Filed: Dec. 13, 2006

(30) Foreign Application Priority Data
Jun. 30, 2006 (JP) 2006-180609

(51) Int. Cl. H05K 1/00; B29C 65/00

(52) U.S. Cl. 361/748; 156/60

(57) ABSTRACT

A manufacturing method for a substrate with a stiffener is disclosed, the substrate being capable of ensuring a good flatness of a printed board when heated to a high temperature and then cooled. The method comprises a first step of preparing a printed board and a stiffener, the printed board including a wiring part and an insulating part formed of an organic insulating material, and the stiffener being formed of a material with a smaller coefficient of thermal expansion than that of the material of the printed board, and a second step of bonding the printed board and the stiffener with a thermosetting adhesive. In the second step, a curing process temperature for curing the thermosetting adhesive is equal to or higher than the glass transition point of the organic insulating material.

This application claims foreign priority based on Japanese Patent Application No. 2006-180609 filed on Jun. 30, 2006, which is hereby incorporated by reference herein in its entirety as if fully set forth herein.

### BACKGROUND OF THE INVENTION

The present invention relates to a substrate with a stiffener which is manufactured by bonding a printed board including an organic insulating material and a stiffener, and to a manufacturing method for the substrate.

LSI packages in which an LSI bare-chip is flip-mounted on a printed board include an FC-BGA (Flip Chip Bump Grid Array) package, an FC-LGA (Flip Chip Land Grid Array) package, and an FC-PGA (Flip Chip Pin Grid Array) package.

Such LSI packages often use a substrate with a stiffener, which is manufactured by bonding a printed board including an organic insulating material and a stiffener for stiffening the printed board (see Japanese Patent Laid-Open No. 2004-311598, Japanese Patent Laid-Open No. H11-284097), and the article relating to a High-end Pb-free package in Nikkei Electronics, issued on Jan. 3, 2005.

In addition, a higher-density of wiring on the printed board increases the number of terminals connecting to electronic parts, such as an LSI, and reduces the pitch between the connecting terminals. Further, since the increase of the number of the connecting terminals and the reduction of the pitch reduce the sizes thereof, an extremely good flatness of the printed board is required for mounting the electronic parts thereon.

As shown in FIG. 11, a printed board 201 that is used for a conventional substrate with a stiffener is provided, in the central part in its thickness direction, with a core layer C reinforced by a glass cloth or the like. On both sides of the core layer C, build-up layers B are provided. Each build-up layer B is formed by laminating plural wiring layers, each of which is constituted by an organic insulating part 213 and a wiring part including wiring patterns 211, connecting vias 212 and the like. 214 denotes a through-hole which penetrates the core layer C and electrically connects the wiring layers provided on both sides thereof. In this substrate, the flatness of the printed board 201 is ensured by providing the core layer C with a high stiffness in the printed board 201.

However, recently, a reduction of the thickness of the entire LSI package is required, and thus a reduction of the thickness of the printed board is also required. Therefore, the core layer used in the conventional printed board is eliminated, and instead, a substrate with a stiffener that is formed by a thin printed board (hereinafter, referred to as an organic board, and see FIG. 2) constituted only by a build-up layer and a stiffener bonded thereto is used.

For the thin organic board with no core layer, however, it is difficult to ensure its flatness only with the stiffener. This will be explained with reference to FIGS. 10A to 10D.

In FIG. 10A, an organic board 201 before bonding of a stiffener is shown. The surface of the organic board 201 is provided with plural pads 205 on which an LSI bare-chip is soldered and mounted.

In FIG. 10B, a flame-shaped stiffener 202 formed of Cu, SUS, A1, or the like is mounted on the upper surface of the organic board 201 so as to surround the plural pads 205. A thermosetting adhesive 203 is provided between the organic board 201 and the stiffener 202. The organic board 201 and the stiffener 202 are pressed to each other with a jig, not, shown, to restrain their movement.

Then, the thermosetting adhesive 203 is heated together with the organic board 201 and the stiffener 202 to be cured. An epoxy resin adhesive is generally used as the thermosetting adhesive 203, and its curing process temperature is about 100 degrees C. The thermosetting adhesive is sometimes heated to a temperature of about 150 degrees C. to increase the curing speed.

At this point, although the coefficient of thermal expansion of the organic board 201 (25 to 30 ppm/K, for example) is considerably larger than that of the stiffener 202 (17.3 ppm/K for Cu, for example), the bonding process is finished while a relative displacement of the organic board 201 and the stiffener 202 due to their thermal expansions is suppressed by the above-mentioned restraining jig.

After that, when they are cooled to a room temperature, since the organic board 201 whose coefficient of thermal expansion is larger than that of the stiffener 202 shrinks more than the stiffener 202, warpage of the organic board 201 is reduced.

However, when this substrate with the stiffener is heated to a temperature of about 240 to about 260 degrees C., which is a solder melting temperature, for mounting the LSI bare-chip 204 on the substrate, since the coefficient of thermal expansion of the organic board 201 is larger than that of the stiffener 202 as described above, large warpage or undulation of the organic board 201 occurs as shown in FIG. 10C. This makes it difficult to mount the LSI bare-chip on the substrate as shown in FIG. 10D.

### BRIEF SUMMARY OF THE INVENTION

The present invention provides a substrate with a stiffener, which is capable of ensuring a good flatness of a printed board when heated to a high temperature and then cooled.

The present invention in its first aspect provides a method for manufacturing a substrate with a stiffener which comprises a first step of preparing a printed board and a stiffener, the printed board including a wiring part and an insulating part formed of an organic insulating material, and the stiffener being formed of a material with a smaller coefficient of thermal expansion than that of the material of the printed board, and a second step of bonding the printed board and the stiffener with a thermosetting adhesive. In the second step, a curing process temperature for thermosetting adhesive is equal to or higher than the glass transition point of the organic insulating material.

The present invention in its second aspect provides a substrate with a stiffener which comprises a printed board which includes a wiring part and an insulating part formed of an organic insulating material, a stiffener which is formed of a material with a smaller coefficient of thermal expansion than that of the material of the printed board, and a thermosetting adhesive which is used for bonding the printed board and the stiffener. The thermosetting adhesive was cured at a curing process temperature equal to or higher than the glass transition point of the organic insulating material.

The present invention in its other aspects provides an electronic device which comprises a substrate with a stiffener which is manufactured by the above-mentioned method and an electronic device which comprises the above-mentioned substrate with a stiffener.

Other objects and features of the present invention will become readily apparent from the following description of the preferred embodiments with reference to accompanying drawings.

### BRIEF DESCRIPTION OF THE DRAWINGS

FIG. 1A is a sectional side view showing a package substrate which is an embodiment of the present invention.

FIG. 1B is a plane view showing the package substrate of the embodiment.

FIG. 2 is an enlarged section view showing an organic board used in the package substrate of the embodiment.

FIGS. 3A to 3D are schematic views showing a manufacturing method for the package substrate of the embodiment.

FIG. 4 is a flowchart showing the manufacturing method for the package substrate of the embodiment.

FIGS. 5A to 5F are schematic views showing the manufacturing process for the package substrate of the embodiment.

FIG. 6 is a graph showing the characteristic of an organic insulating material which constitutes the organic board shown in FIG. 2.

FIG. 7 is a table showing the properties of materials for a stiffener which is used in the package substrate in the embodiment and a modified example.

FIG. 8 is a graph showing the results of experiments for measuring a curing reaction rate of a thermosetting adhesive in the embodiment.

FIG. 9 is a schematic view showing an electronic device which uses the package substrate of the embodiment.

FIGS. 10A to 10D are schematic views showing a manufacturing method for a conventional package substrate.

FIG. 11 is an enlarged section view showing a conventional printed board including a core layer.

### DETAILED DESCRIPTION OF THE PREFERRED EMBODIMENTS

Preferred embodiments of the present invention will hereinafter be described with reference to the accompanying drawings.

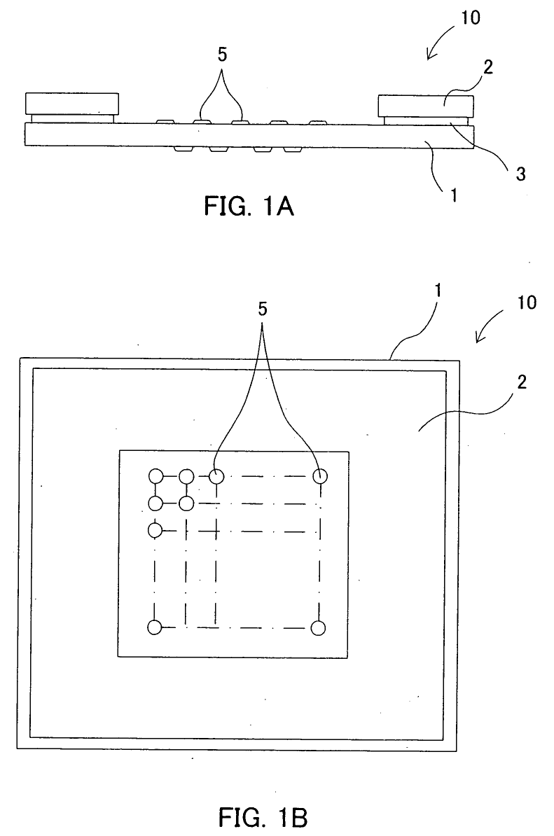

FIGS. 1A and 1B schematically show the structure of a package substrate (substrate with a stiffener) which is an embodiment of the present invention. FIG. 1A is a sectional side view showing the package substrate, and FIG. 1B is a plane view showing the package substrate.

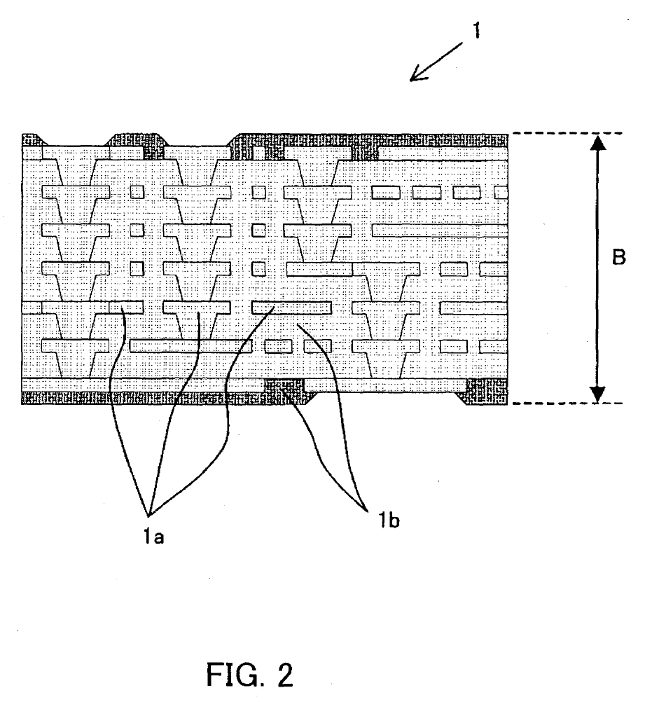

In these figures, 1 denotes a rectangular printed board. This printed board 1 is a build-up multilayer substrate, which has no core layer and is constituted only by a build-up layer B as shown in FIG. 2 which is an enlarged view of part of the printed board 1.

The build-up layer B is constituted by wiring parts 1a which includes wiring patterns and connecting vias that are formed by a metal material with high electrical conductivity such as Cu and insulating parts 1b which insulates the wiring parts 1a. The insulating part 1b is formed of an organic material with high electrical insulating properties such as an epoxy resin. Hereinafter, the printed board 1 is referred to as the organic board 1.

As shown in FIGS. 1A and 1B, plural soldering pads (connecting terminals) 5 are formed on the first surface of the organic board 1. The soldering pads 5 are provided for a so-called flip-chip mount of electronic parts such as an LSI bare-chip. Plural soldering pads for mounting the manufactured package substrate 10 on another circuit board, not shown, are formed on the back surface of the organic board 1.

On the first surface of the organic board 1, a stiffener 2, which is a stiffening member and has a rectangular shape surrounding an area where the soldering pads 5 are provided (electronic parts mounting area), is bonded with a thermosetting adhesive 3. The thermosetting adhesive 3 consists primarily of an epoxy resin. The stiffener 2 is formed of a metal material such as Cu, SUS and A1. The stiffener 2 is provided for ensuring stiffness and flatness of the package substrate 10 and entire LSI package with the mounted electronic parts.

The shapes of the organic board 1 and the stiffener 2 described in this embodiment are only illustrative, and the shape may be a circular shape, a ring shape or the like. In addition, the thermosetting adhesive 3 may be formed of materials other than the epoxy resin.

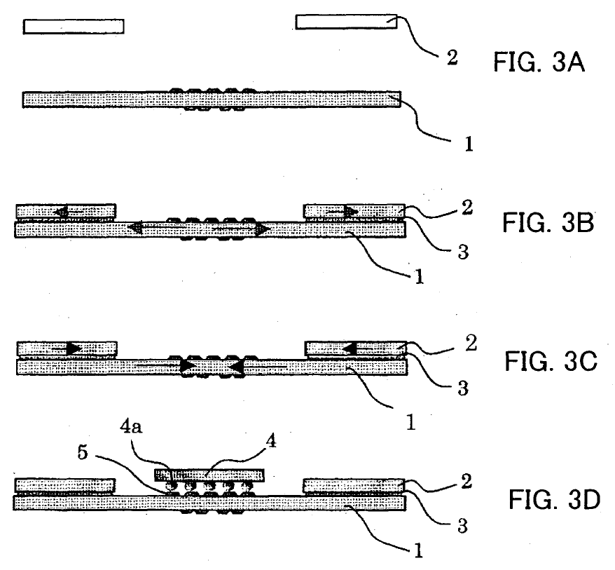

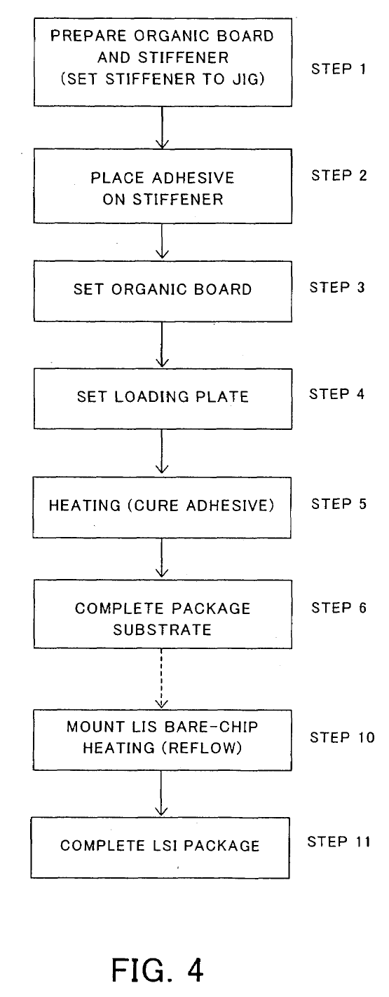

FIGS. 3A to 3D and 4 show the manufacturing process for the package substrate of this embodiment. In this embodiment, the coefficient of thermal expansion of the organic board 1 is 25 to 30 ppm/K, wherein that of the organic insulating part 1b is 50 to 80 ppm/K and that of the Cu wiring part 1a is 17.3 ppm/K. The stiffener 2 is formed of Cu and its coefficient of thermal expansion is 17.3 ppm/K.

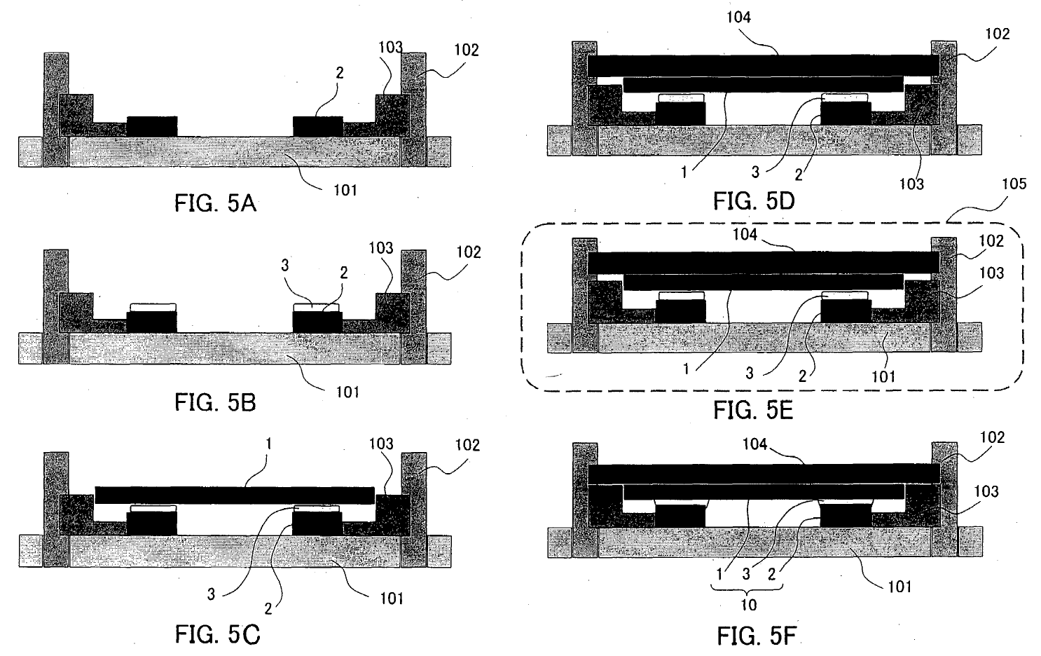

Further, FIG. 5A shows a jig that is used in the manufacturing process in this embodiment. The jig is constituted by a stage 101 that is a base, positioning pins 102 that are fixed to the stage 101, and positioning guide members 103 that are fixed to the stage 101 and the positioning pins 102. In addition, the jig has a loading plate 104 with a predetermined weight as shown in FIG. 5D.

FIGS. 5A to 5F show the manufacturing process of the package substrate corresponding to steps shown in FIGS. 3A to 3D and 4.

At step 1 shown in FIG. 4, the organic board 1 and the stiffener 2 are prepared as shown in FIG. 3A. Specifically, the stiffener 2 is placed on the stage 101 of the jig as shown in FIG. 5A first. At this point, the stiffener 2 is positioned by the lower step portions of the guide members 103, which are located around the stiffener 2.

It should be noted that the positioning of the stiffener 2 is performed such that an outward thermal expansion of the stiffener 2 in its in-plane direction (in the horizontal direction in the figure) is allowed in the later-described curing process of the thermosetting adhesive 3.

Next, at step 2 shown in FIG. 4, the thermosetting adhesive 3 is placed on the upper surface (lower surface in FIG. 3A) of the stiffener 2 as shown in FIG. 5B.

Next, at step 3 shown in FIG. 4, the organic board 1 is placed on the thermosetting adhesive 3 as shown in FIG. 5C. At this point, the organic board 1 is positioned by the upper step portions of the guide members 103, which are located around the organic board 1.

It should be noted that the positioning of the organic board 1 is performed such that an outward thermal expansion of the organic board 1 in its in-plane direction is allowed in the later-described curing process.

Next, at step 4 shown in FIG. 4, the loading plate 104 is placed on the organic board 1 as shown in FIG. 5D. The loading plate 104 is held such that the movement thereof in its in-plane direction is prevented by the positioning pins 102 while the movement thereof in its thickness direction is allowed.

The weight of the loading plate 104 is selected so as to keep the parallel relationship between the organic board 1 and the stiffener 2, that is, the uniformity of the thickness of the package substrate and to allow outward elongations of the organic board 1 and the stiffener 2 due to their thermal expansions in their in-plane directions until the thermosetting adhesive 3 is completely cured in the curing process. In other words, heating in the curing process is allowed in a state in which the organic board 1 and the stiffener 2 are pressed to each other in their thickness directions with a small force that does not restrain their outward elongations due to the thermal expansion.

Next, at step 5 shown in FIG. 4, heating (the curing process) is performed for bonding the organic board 1 and the stiffener 2 by curing of the thermosetting adhesive 3 as shown in FIG. 3B. Specifically, as shown in FIG. 5E, the organic board 1, the stiffener 2 and the jig, which have been set as shown FIG. 5D, are placed in an oven 105 and then heated to a predetermined curing process temperature Ta.

A thermosetting adhesive is used as the adhesive 3 in which its curing reaction rate is equal to or less than 20% when (immediately after) the temperature of the adhesive reaches the curing process temperature Ta and which is completely cured by heating for a few minutes to a few ten minutes at the curing process temperature Ta.

The curing process temperature Ta is a temperature equal to or higher than the glass transition point Tg of the organic insulating material.

The curing reaction rate is calculated or estimated from a heat quantity per unit weight, which is obtained by an apparatus for analyzing thermal curing reactions, immediately after reaching the curing process temperature. The apparatus includes a DAT (Differential Thermal Analyzer) and a DSC (Differential Scanning Calorimeter).

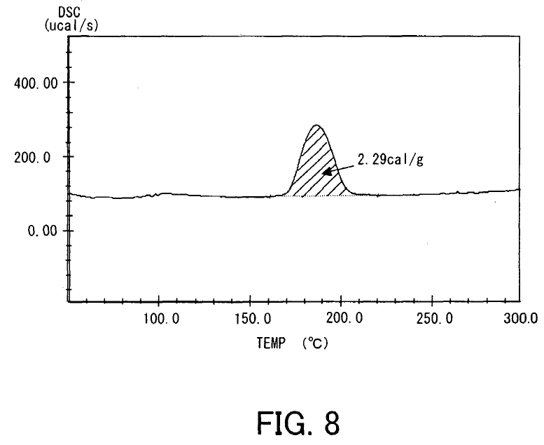

For example, FIG. 8 shows the experimental result of the curing reaction rate analysis in which the adhesive 3 is heated to a temperature of 300 degrees C. at a rate of temperature increase of 10 degrees C./min.

The hatched part in the figure shows 2.29 cal/g, and the curing reaction rate can be calculated from the area coefficient ratio of this part.

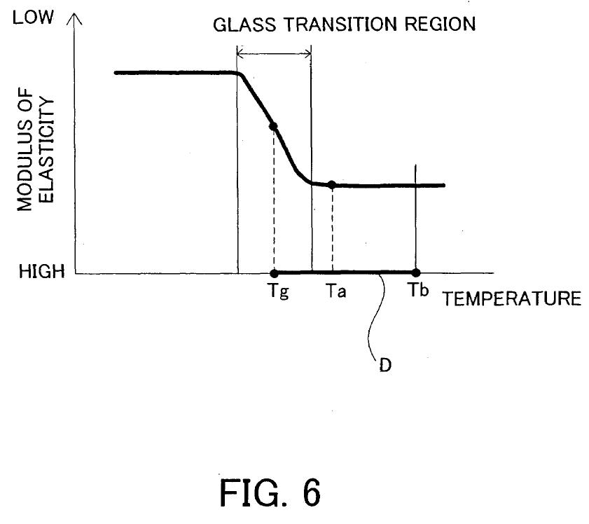

The curing process temperature Ta in this embodiment will hereinafter be described with reference to FIG. 6. FIG. 6 shows the relationship between the temperature of the organic insulating material constituting the organic board 1 and the modulus of elasticity thereof. Tg represents the glass transition point of the organic insulating material, and a region of about 10 degrees C. centered on this temperature Tg is the glass transition region. The modulus of elasticity of the organic insulating material changes widely in the glass transition region. Specifically, the modulus of elasticity dramatically reduces from the low temperature region to the high temperature region.

In this embodiment, the curing process temperature Ta is set to a temperature equal to or higher than the glass transition point Tg. In a case where an epoxy resin is used as the organic insulating material, the glass transition point Tg is a temperature from 100 to 150 degrees C. Therefore, the curing process temperature Ta is set to a temperature equal to or higher than 150 degrees C., for example, a temperature of 175 degrees C.

The temperature of 175 degrees C. is not only a temperature equal to or higher than the glass transition point Tg but also a temperature equal to or higher than the highest temperature of the glass transition region. Selecting such a curing process temperature Ta equal to or higher than the highest temperature of the glass transition region can cure the adhesive 3 after the organic insulating material is sufficiently softened and its properties are stable. Accordingly, it is easy to control the amount of thermal expansion of the organic board 1.

Although methods for measuring the glass transition point Tg include the DSC (Differential Scanning Calorimetry) method, the TMA (Thermomechanical Analysis) method, the DMA (Dynamic Mechanical Analysis) method and the like, any method can be employed in this embodiment.

In addition, the curing process temperature Ta is preferably a temperature equal to or higher than the glass transition point Tg and equal to or lower than the later-described temperature Tb for mounting electronic parts (hereinafter, the temperature Tb is referred to as the part-mounting temperature) as shown by the region D in FIG. 6.

Furthermore, an adhesive made of a crystalline epoxy resin is preferably used as the adhesive 3, which has crystalline properties at ordinary (room) temperature and whose melting point is a temperature from 100 to 180 degrees C. This kind of adhesive can be easily made by blending commercial adhesives. The melting point of the adhesive 3 may be a temperature equal to or higher than 110 degrees C. or a temperature equal to or higher than 120 degrees C.

In the experiments, the adhesive 3 was made by blending YX4000 made by Japan Epoxy Resins Co., Ltd. (biphenyl-type epoxy, EW195, melting point 120 degrees C.) and TIPC made by Nissan Chemical Industries, Ltd. (triglycidyl isocyanurate, EW110, melting point 120 degrees C.) at a ratio at which the above-mentioned curing reaction rate characteristic can be obtained.

In the curing process of the adhesive 3, since the organic board 1 and the stiffener 2 are not subjected to a restraint by the jig and the adhesion force of the adhesive 3, they expand (extend) in accordance with their original coefficients of thermal expansion. After the adhesive 3 is cured, the organic board 1 is subjected to a restraint by the stiffener 2, that is, they are integrated with each other.

As described above, in this embodiment, the heating temperature is increased to a temperature equal to or higher than the glass transition point Tg of the organic insulating material before the thermal curing reaction of the adhesive 3 starts and the force of restraint by the adhesion is generated (that is, in a state in which the curing reaction rate is equal to or less than 20%). This makes it possible to bond the organic board 1 and the stiffener 2 in a state in which the original thermal expansions thereof are generated at least until the heating temperature reaches the glass transition point Tg. In other words, the thermal expansion of the organic board 1 is allowed without a restraint by the cured adhesive 3 at least until the heating temperature reaches the glass transition point Tg.

After the adhesive 3 is completely cured, the organic board 1 and stiffener 2 are cooled to a low temperature region such as a room temperature as shown in FIG. 5F. The package substrate 10 is thus completed at step 6 in FIG. 4 and as shown in FIG. 3C.

In the cooling process, the organic board 1 and the stiffener 2 shrink as shown in FIG. 3C. Since the coefficient of thermal expansion of the organic board 1 is larger than that of the stiffener 2, a larger shrinkage force is generated in the organic board 1. At this point, the peripheral part of the organic board 1 is fixed (restrained) by the stiffener 2 via the adhesive 3. Therefore, a tension is generated in the organic board 1, thereby ensuring a high flatness of the organic board 1.

Next, the process for flip-chip mounting of an LSI bare-chip on the completed package substrate 10 will be described with reference to FIGS. 3D and 4. As shown in FIG. 3D, the back surface of the LSI bare-chip 4 is provided with plural terminals, and a solder ball (solder bump) 4a is provided on each of the terminals.

At step 10 in FIG. 4, the positions of the soldering pads 5 of the package substrate 10 and those of the solder balls 4a on the LSI bare-chip 4 are adjusted, and then they are brought into contact with each other. Then, the package substrate 10 and the LSI bare-chip 4 are placed in a reflow furnace, not shown, and heated to the predetermined part-mounting temperature Tb. The part-mounting temperature Tb is a temperature at which the solder ball 4a reflows and a temperature from about 240 degrees C. to about 260 degrees C., which is higher temperature than the curing process temperature Ta.

The heating to the part-mounting temperature Tb causes the thermal expansions of the organic board 1 and the stiffener 2. As described above, the amount of the thermal expansion of the organic board 1 is larger than that of the stiffener 2. However, since the temperature in the curing process was increased to the glass transition point Tg of the organic insulating material before the force of restraint by the adhesive 3 was generated, almost no warpage and undulation occur in the organic board 1 at least until the glass transition point Tg.

Furthermore, in the temperature region above the glass transition point Tg, the organic insulating material is dramatically softened, so that the coefficient of thermal expansion of Cu which is a material of the wiring part 1a is dominant on that of the organic board 1.

In other words, the coefficient of thermal expansion of the organic board 1 becomes equivalent to that of the stiffener 2 formed of Cu. As a result, the amount of the thermal expansion of the organic board 1 is equivalent to that of the stiffener 2 in the temperature region from the glass transition point Tg to the part-mounting temperature Tb, thereby preventing the warpage and undulation of the organic board 1.

As described above, curing the adhesive 3 at a curing temperature equal to or higher than the glass transition point Tg makes it possible to suppress deformation (such as warpage) of the organic board 1 to ensure a good flatness thereof when mounting the LSI bare-chip 4 on the package substrate 10 at the part-mounting temperature Tb higher than the curing temperature. Consequently, it is possible to solder the plural solder balls 4a provided on the LSI bare-chip 4 to the plural soldering pads 5 provided on the package substrate 10 uniformly, thereby ensuring an appropriate mounting of the LSI bare-chip 4.

Further, in a state in which the package substrate 10 is cooled to a room temperature or the like after heating for mounting the LSI bare-chip 4, since the peripheral part of the organic board 1 is restrained by the stiffener 2 via the adhesive 3, a tension is generated in the organic board 1 to ensure a good flatness thereof. Therefore, cracks and peeling of the solder are prevented after mounting the LSI bare-chip 4, thereby maintaining an appropriate mounted state.

In this embodiment, a thermosetting epoxy adhesive is used as the thermosetting adhesive 3. This is because the thermosetting epoxy adhesive is most appropriate in view of the temperature required for reflowing the solder when the parts are mounted, and the heat resistance (for example, 260 degrees C.) and strength required for the LSI package.

On the other hand, glass transition points of organic insulating materials in epoxy, which are used for the organic board, are generally at a temperature from about 100 degrees C. to about 150 degrees C. Almost all conventional thermosetting epoxy adhesives cure at a temperature of about 100 degrees C., and therefore the curing process is generally performed at a temperature lower than the glass transition point of the organic insulating material.

There was no problem in the past because the coefficient of thermal expansion of a printed board including a core layer was close to that of materials of a stiffener, such as Cu and SUS, and therefore there was little case where the difference between the curing process temperature of an adhesive and the part-mounting temperature adversely affected the flatness of the substrate after bonding of the stiffener.

However, in the case where the thin organic board without a core layer is used as in this embodiment, the coefficient of thermal expansion of the entire substrate formed by a combination of the organic insulating material and the wiring material (chiefly, Cu) is equal to or higher than 25 ppm/K. Therefore, using a conventional stiffener formed of a metal material such as Cu and SUS generates a large difference of the coefficients of thermal expansion equal to or more than 7 ppm/K, thereby causing a problem of deformation of the organic board due to the above temperature difference.

Thus, in this embodiment, the curing process temperature for the thermosetting adhesive 3 is set to a temperature equal to or higher than the glass transition point Tg of the organic insulating material. In other words, the thermosetting adhesive 3 is used in which its curing reaction rate is equal to or less than 20% when the temperature thereof reaches the curing process temperature equal to or higher than the glass transition point Tg. This makes it possible to certainly and easily solve the above problem.

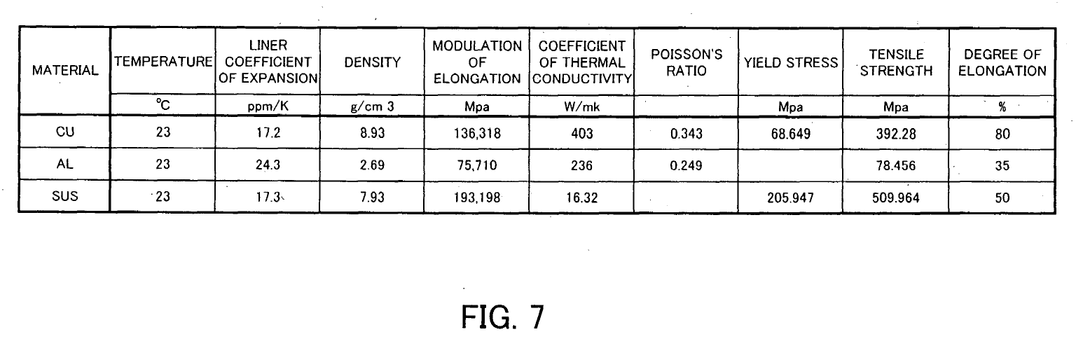

FIG. 7 shows the properties of Cu that is the material of the stiffener 2 in this embodiment and those of SUS and A1, which may be used instead of Cu.

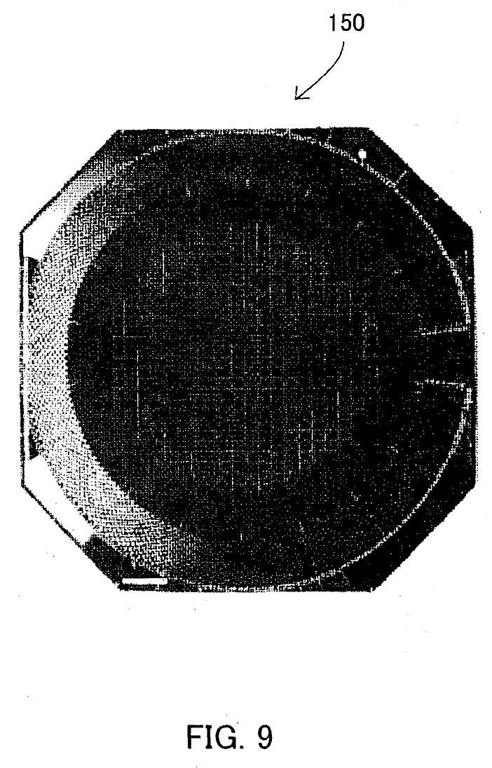

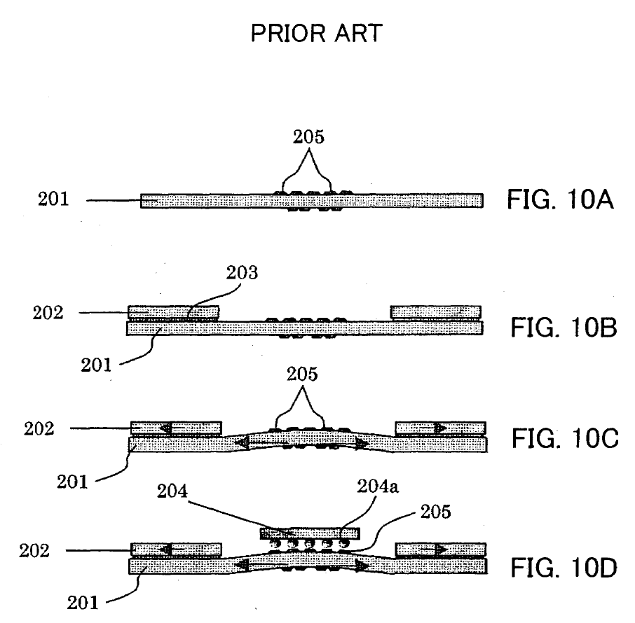

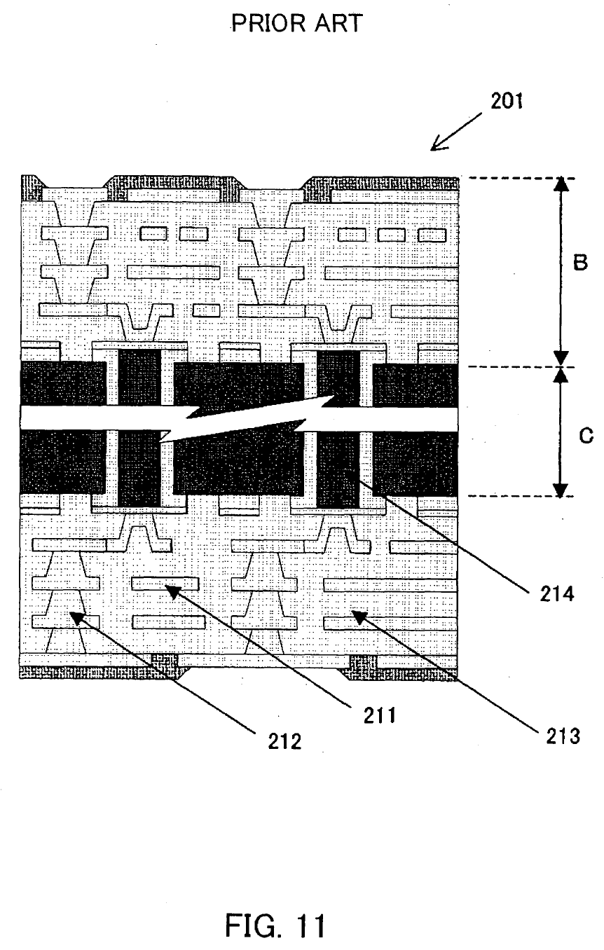

The LSI package manufactured as above is used for a tester board (electronic device) for LSI wafers. FIG. 9 shows a plane view of the tester board in which the LSI package in this embodiment is employed. However, the present invention can be widely applied not only to the tester board for LSI wafers but also to build-up substrates used in other electronic devices such as laptop personal computers, digital cameras, server computers, and cellular phones.

In addition, the structure of the package substrate and the manufacturing method thereof described in the above embodiment can be applied to all kind of flip-chip mounted substrates such as an FC-BGA package, an FC-LGA package, and an FC-PGA package.

According to the above-described embodiment, when heating to a temperature higher than the curing process temperature of the adhesive to mount electronic parts on the substrate with the stiffener, warpage and undulation of the printed board can be reduced to ensure a good flatness thereof. Consequently, it is possible to certainly and appropriately mount the electronic parts on the substrate even if the number of connecting terminals is increased more than ever and the pitch of the terminals is smaller than ever. Further, warpage or the like of the substrate can be reduced after mounting the parts.

In addition, since the curing process temperature of the thermosetting adhesive is a temperature equal to or higher than the glass transition point of the organic insulating material, the thermal expansion of the printed board is allowed without a restraint by the cured adhesive at least until the heating temperature reaches the glass transition point. Therefore, it is possible to bond the printed board and the stiffener in a state in which the printed board has little warpage and undulation.

Furthermore, in a temperature region above the glass transition point and the curing process temperature, the modulus of elasticity of the organic insulating material is widely reduced, so that the coefficient of thermal expansion of the printed board is dominated by that of a metal material constituting the wiring part. Therefore, the difference between the coefficients of thermal expansion of the printed board and stiffener is small, thereby preventing the warpage and undulation of the printed board at the part-mounting temperature.

Consequently, it is possible to mount the parts on the printed board with a good flatness. Further, since a tension is generated in the cooled printed board, it is possible to ensure the flatness of the printed board. Therefore, it is possible to keep the flatness of the printed board after mounting parts.

Specifically, the thermosetting adhesive is preferably an adhesive whose curing reaction rate is equal to or less than 20% when its temperature reaches the curing process temperature that is equal to or higher than the glass transition point of the organic insulating material. Thereby, as described above, the thermal expansion of the printed board is allowed without a restraint by the cured adhesive at least until the heating temperature reaches the glass transition point.

Moreover, during heating for curing process of the adhesive, the printed board and the stiffener are preferably pressed to each other in their thickness directions in a state in which their outward thermal expansions in their in-plane directions are allowed, that is, in a state in which their thermal expansions are not restrained. This makes it possible to maintain the parallel relationship between the printed board and the stiffener (that is, uniformity of the thickness of the substrate) in the curing process of the adhesive. In addition, this makes it possible for the printed board and the stiffener to expand in accordance with their original coefficients of thermal expansion without the restraint due to the pressing force.

While the preferred embodiment of the present invention has been described, it goes without saying that the present invention is not limited to the abovementioned embodiment and various modifications and variations may be made without departing from the spirit or scope of the present invention.

What is claimed is:

1. A method for manufacturing a substrate with a stiffener comprising:
a first step of preparing a printed board and a stiffener, the printed board including a wiring part and an insulating part formed of an organic insulating material, and the stiffener being formed of a material with a smaller coefficient of thermal expansion than that of the material of the printed board; and
a second step of bonding the printed board and the stiffener with a thermosetting adhesive,
wherein, in the second step, a curing process temperature for curing the thermosetting adhesive is equal to or higher than the glass transition point of the organic insulating material.

2. The method according to claim 1, wherein the curing process temperature is equal to or higher than the highest temperature in the glass transition region of the organic insulating material.

3. The method according to claim 1, wherein the curing process temperature is equal to or lower than a heating temperature for mounting electronic parts on the printed board.

4. The method according to claim 1, wherein, in the second step, the curing reaction rate of the thermosetting adhesive is equal to or less than 20% when the temperature of the thermosetting adhesive reaches the curing process temperature.

5. The method according to claim 1, wherein the melting point of the thermosetting adhesive is at a temperature from 100 degrees C. to 180 degrees C.

6. The method according to claim 1, wherein, in the second step, the printed board and the stiffener are pressed to each other in a state in which outward thermal expansions of the printed board and the stiffener in their in-plane directions are allowed.

7. The method according to claim 1, wherein the printed board is a build-up multilayer substrate with no core layer.

8. A substrate with a stiffener comprising:
a printed board which includes a wiring part and an insulating part formed of an organic insulating material;
a stiffener which is formed of a material with a smaller coefficient of thermal expansion than that of the material of the printed board; and
a thermosetting adhesive which is used for bonding the printed board and the stiffener,
wherein, the thermosetting adhesive was cured at a curing process temperature equal to or higher than the glass transition point of the organic insulating material.

9. The substrate according to claim 8, wherein the thermosetting adhesive has a characteristic in which the curing reaction rate thereof is equal to or less than 20% when the temperature of the thermosetting adhesive reaches the curing process temperature.

10. The substrate according to claim 8, wherein the melting point of the thermosetting adhesive is at a temperature from 100 degrees C. to 180 degrees C.

11. The substrate according to claim 8, wherein the curing process temperature is equal to or higher than the highest temperature in the glass transition region of the organic insulating material.

12. The substrate according to claim 8, wherein the curing process temperature is equal to or lower than a heating temperature for mounting electronic parts on the printed board.

13. The substrate according to claim 8, wherein the printed board is a build-up multilayer substrate with no core layer.

14. An electronic device comprising a substrate with a stiffener, the substrate being manufactured by the method according to claim 1.

15. An electronic device comprising a substrate with a stiffener according to claim 8.
